(19) United States
(12) Patent Application Publication
(10) Pub. No.: US 2022/0268980 A1
(43) Pub. Date: Aug. 25, 2022

(54) COLOR FILTER AND METHOD OF MANUFACTURING THEREOF

(71) Applicant: Wuhan China Star Optoelectronics Semiconductor Display Technology Co., Ltd., Wuhan, Hubei (CN)

(72) Inventors: Zhengfeng ZHU, Wuhan, Hubei (CN); Wenliang GONG, Wuhan, Hubei (CN)

(21) Appl. No.: 17/089,966

(22) PCT Filed: Jul. 20, 2020
(86) PCT No.: PCT/CN2020/103005

§ 371 Date: Nov. 5, 2020

(30) Foreign Application Priority Data
Jun. 23, 2020 (CN) 202010580281.8

(51) Int. Cl. G02B 5/20

(52) U.S. Cl. CPC G02B 5/201

(57) ABSTRACT

A color filter and a method of manufacturing thereof are provided. The color filter includes a substrate, a black matrix block, and a color resist unit. The black matrix block includes a first black matrix unit and a second black matrix unit. The black matrix unit is composed of a hydrophilic material. and the second black matrix unit is composed a hydrophobic material. Only one color resist unit is disposed between any two adjacent black matrix blocks, and a side of the color resist unit away from the substrate includes a convex arc shape.

### BACKGROUND OF INVENTION

### Field of Invention

The present invention relates to the field of display technology, and more particularly, to a color filter and a method of manufacturing thereof.

### Description of Prior Art

Organic light emitting diode display technology has been widely used in flexible display devices due to its advantages of self-luminescence, low power consumption, lightness, thinness, and no liquid crystal layer. Flexible organic light emitting diode devices usually include thin film transistors based on flexible substrates, light emitting layers, packaging layers based on multilayer thin films, and circular polarizers. As for organic light emitting diode devices, the polarizes may reduce reflectivity of ambient light, increase its contrast, and improve the outdoor readability of organic light emitting diodes, but they also lose about 58% of light. In addition, due to their large thickness and brittle texture, they also limit the development of dynamic bendable display products. Therefore, organic light emitting diode devices in the prior art adopt color filters instead of polarizers to solve above-mentioned problems.

Currently, color filters are generally manufactured by inkjet printing technology. At first, a black matrix is formed as a blocking unit so as to form pixel pits, and then ink is dropped into the pixel pits to solidify the ink to form a color resist unit. Currently, solid content of the ink is low, and it forms a concave surface after curing. Moreover, after the ink is dropped into the pixel pit, phenomenon of ink hanging on the black matrix is also very serious, so it is necessary to increase a thickness of color resistance unit by increasing a thickness of the black matrix, but the thickness of the color resist unit cannot be well controlled.

Therefore, how to effectively control the thickness of the color resistance unit in the color filter is a difficult problem that panel manufacturers all over the world are trying to overcome.

### SUMMARY OF INVENTION

A color filter and a method of manufacturing thereof are provided, which may solve the technical problem that a thickness of the color resistance unit in the color filter of the prior art cannot be effectively controlled.

A color filter comprises a substrate, a plurality of black matrix blocks, and a plurality of color resist units. The plurality of black matrix blocks are disposed on the substrate at intervals, and each of the black matrix blocks comprises a first black matrix unit and a second black matrix unit disposed on the first black matrix unit. In any two adjacent black matrix blocks, a spacing between two adjacent first black matrix units is less than a spacing between two adjacent second black matrix units; wherein the first black matrix unit is composed of a hydrophilic material, and the hydrophilic material comprises at least one of metal oxides and metal sulfides; and wherein the second black matrix unit is composed of a hydrophobic material, and the second black matrix unit comprises at least one of fluorine-containing organic resin and fluorine-free acrylate. The plurality of color resist units are disposed on the substrate, only one of the color resist units is disposed between any two adjacent black matrix blocks, and a surface side of each of the color resist units away from the substrate comprises a convex arc shape.

In one embodiment, the first black matrix unit and the second black matrix unit comprise a trapezoid shape.

In one embodiment, the first black matrix unit comprises a first side and a second side, the first side is opposite to the second side, the first side is close to the substrate, and the second side is far away from the substrate. The second black matrix unit comprises a third side and a fourth side, the third side is opposite to the fourth side, the third side is close to the substrate, and the fourth side is far away from the substrate. The second side is attached to the third side.

In one embodiment, the second side is completely attached to the third side.

In one embodiment, a length of the second side is equal to a length of the third side, and a thickness of the color resist unit is equal to a thickness of the first black matrix unit.

In one embodiment, when a length of the second side is equal to a length of the third side and a thickness of the first black matrix unit is greater than a thickness of the second black matrix unit, a thickness of the color resist unit is equal to a total thickness of the first black matrix unit and the second black matrix unit.

In one embodiment, the second side is incompletely attached to the third side.

In one embodiment, a length of the second side is greater than a length of the third side. The color resist unit comprises a first part and a second part disposed on the first part. A thickness of the first part is equal to a thickness of the first black matrix unit, and the first part comprises a trapezoid shape. A thickness of the second part is less than a thickness of the second black matrix unit, and the second part comprises an arc shape.

A color filter comprises a substrate, a plurality of black matrix blocks, and a plurality of color resist units. The plurality of black matrix blocks are disposed on the substrate at intervals, and each of the black matrix blocks comprises a first black matrix unit and a second black matrix unit disposed on the first black matrix unit; and wherein the first black matrix unit is composed of a hydrophilic material, and the second black matrix unit is composed of a hydrophobic material. The plurality of color resist units are disposed on the substrate, only one of the color resist units is disposed between any two adjacent black matrix blocks, and a surface side of each of the color resist units away from the substrate comprises a convex arc shape.

In one embodiment, the first black matrix unit comprises at least one of metal oxides and metal sulfides.

In one embodiment, the second black matrix unit comprises at least one of fluorine-containing organic resin and fluorine-free acrylate.

In one embodiment, in any two adjacent black matrix blocks, a spacing between two adjacent first black matrix units is less than a spacing between two adjacent second black matrix units.

In one embodiment, the first black matrix unit and the second black matrix unit comprise a trapezoid shape.

In one embodiment, the first black matrix unit comprises a first side and a second side, the first side is opposite to the second side, the first side is close to the substrate, and the second side is far away from the substrate. The second black matrix unit comprises a third side and a fourth side, the third side is opposite to the fourth side, the third side is close to the substrate, and the fourth side is far away from the substrate. The second side is attached to the third side.

In one embodiment, the second side is completely attached to the third side.

In one embodiment, a length of the second side is equal to a length of the third side, and a thickness of the color resist unit is equal to a thickness of the first black matrix unit.

In one embodiment, when a length of the second side is equal to a length of the third side and a thickness of the first black matrix unit is greater than a thickness of the second black matrix unit, a thickness of the color resist unit is equal to a total thickness of the first black matrix unit and the second black matrix unit.

In one embodiment, the second side is incompletely attached to the third side.

In one embodiment, a length of the second side is greater than a length of the third side. The color resist unit comprises a first part and a second part disposed on the first part. A thickness of the first part is equal to a thickness of the first black matrix unit, and the first part comprises a trapezoid shape. A thickness of the second part is less than a thickness of the second black matrix unit, and the second part comprises an arc shape.

A method of manufacturing a color filter comprises:

providing a substrate;

forming a plurality of black matrix blocks arranged at intervals on the substrate, and each of the black matrix blocks comprises a first black matrix unit and a second black matrix unit disposed on the first black matrix unit, the first black matrix unit is composed of a hydrophilic material, and the second black matrix unit is composed of a hydrophobic material; and forming a plurality of color resist units on the substrate, and only one of the color resist units is disposed between any two adjacent black matrix blocks, and a surface side of each of the color resist units away from the substrate comprises a convex arc shape.

In the present invention, a color filter and a method of manufacturing thereof are provided. A black matrix with a double-layer structure is provided, and the double-layer structure of the black matrix is composed of different materials. An upper layer structure of the black matrix is composed of a hydrophobic material. A lower layer structure of the black matrix is composed of a hydrophilic material. Therefore, a thickness of the color filter may be precisely controlled by controlling a size of the upper layer structure of the black matrix and a size of the lower layer structure of the black matrix. Accordingly, technical problem that the thickness of the color resist unit in the color filter of the prior art cannot be effectively controlled is solved.

### BRIEF DESCRIPTION OF DRAWINGS

In order to more clearly illustrate the technical solutions in the embodiments, the drawings described in the description of the embodiments are briefly described below. It is obvious that the drawings in the following description are only some embodiments of the present invention. Other drawings can also be obtained from those skilled persons in the art based on drawings without any creative effort.

FIG. 1 is a schematic structural view of a color filter according to one embodiment of the present invention.

FIG. 2 is a first schematic structural view of a black matrix block and a color resist unit according to one embodiment of the present invention.

FIG. 3 is a second schematic structural view of a black matrix block and a color resist unit according to one embodiment of the present invention.

FIG. 4 is a third schematic structural view of a black matrix block and a color resist unit according to one embodiment of the present invention.

FIG. 5 is a schematic flowchart of a method of manufacturing a color filter according to one embodiment of the present invention.

FIG. 6 is a schematic structural view of a display panel according to one embodiment of the present invention.

### DETAILED DESCRIPTION OF PREFERRED EMBODIMENTS

The technical solutions in this application will be described clearly and completely in conjunction with the drawings in the embodiments of this application. Obviously, the described implementations are only a part of the implementations of the present application, rather than all of the implementations. Based on the implementation manners in this application, all other implementation manners obtained by those skilled in the art without creative work shall fall within the claimed scope of this application.

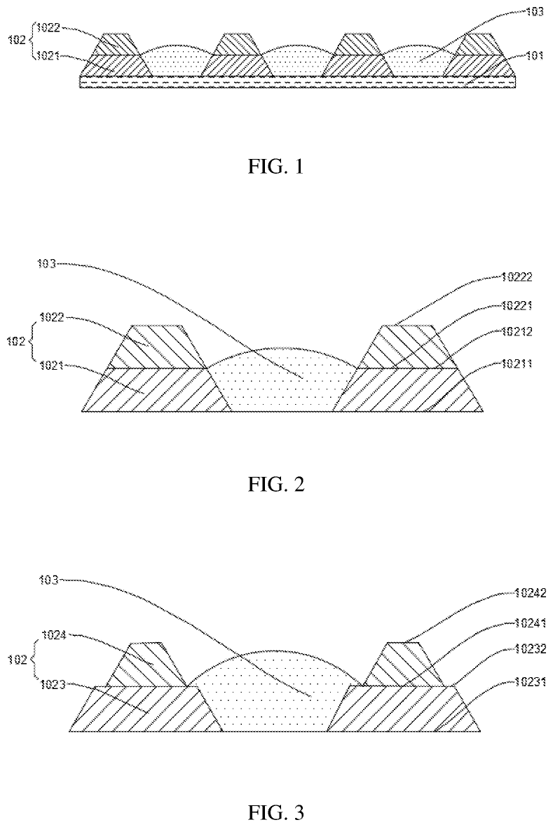

Referring to FIG. 1, it is a schematic structural view of a color filter according to one embodiment of the present invention. A color filter comprises a substrate 101, a plurality of black matrix blocks 102, and a plurality of color resist units 103. The plurality of black matrix blocks 102 are disposed on the substrate 101 at intervals, and each of the black matrix blocks 102 comprises a first black matrix unit 1021 and a second black matrix unit 1022 disposed on the first black matrix unit 1021. The first black matrix unit 1021 is composed of a hydrophilic material, and the second black matrix unit 1022 is composed of a hydrophobic material. A plurality of color resist units 103 are disposed on the substrate 101, and only one of the color resist units 103 is disposed between any two adjacent black matrix blocks 102, and a surface side of each of the color resist units 103 away from the substrate 103 comprises a convex arc shape.

It may be understood that the first black matrix unit 1021 in the black matrix block 102 is composed of a hydrophilic material, and the second black matrix unit 1022 is composed of a hydrophobic material. Therefore, when the color resist unit 103 is formed, the color resist unit is formed by inkjet printing, the ink may not hang on a side wall of the second black matrix unit 1022, so size and appearance of the formed color resist unit 103 may be effectively adjusted by controlling the sizes of the first black matrix unit 1021 and the second black matrix unit 1022, which solves technical problem that the thickness of the color resistance unit 103 in the color filter may not be effectively controlled in the organic light emitting diode devices of the prior art.

It may be understood that the black matrix block 102 has a block function to prevent the ink used to form the color resist unit 103 within a certain spacing from escaping to the adjacent color resist unit 103 when the color resist unit 103 is formed. As a result, the color resist unit 103 are mixed with other colors, and a color filter having effective function cannot be formed. In addition, the black matrix block 102 further may shield the ambient light to prevent the light reflection caused by ambient light entering metal lines and motors.

It may be understood that the first black matrix unit 1021 is composed of a hydrophilic material, and the second black matrix unit 1022 is composed of a hydrophobic material. The hydrophilic material has a small contact angle with the ink material. The hydrophobic material has large contact angle with the ink material. The smaller the contact angle with the ink material, the easier it is to be soaked by the ink material, and thus has better hydrophilicity. From the opposite point of view, the larger the contact angle with the ink material, the less likely it is to be soaked by the ink material, and thus has better hydrophobicity.

In one embodiment, the first black matrix unit 1021 is composed of a hydrophilic material. Specifically, the first black matrix unit 1021 comprises at least one of metal oxides and metal sulfides, such as copper oxide, iron oxide, manganese dioxide, ferrous ferric oxide, molybdenum sulfide, copper sulfide, etc.

In one embodiment, the second black matrix unit 1022 is composed of a hydrophobic material. Specifically, the second black matrix unit 1022 comprises at least one of fluorine-containing organic resin and fluorine-free acrylate.

In one embodiment, in any two adjacent black matrix blocks 102, a spacing between two adjacent first black matrix units 1021 is less than a spacing between two adjacent second black matrix units 1022.

In one embodiment, the first black matrix unit 1021 and the second black matrix unit 1022 comprise a trapezoid shape. The trapezoid shape of the first black matrix unit 1021 and the second black matrix unit 1022 may be a regular trapezoid or an arc-shaped trapezoid. The regular trapezoid has a characteristic that a length of an upper side of the trapezoid is less than a length of a lower side. The arc-shaped trapezoid has a cured side, so that a junction between the cured side and a bottom is smooth.

Referring to FIG. 2, it is a first schematic structural view of a black matrix block and a color resist unit according to one embodiment of the present invention. The black matrix block 102 comprises a first black matrix unit 1021 and a second black matrix unit 1022. The first black matrix unit 1021 comprises a first side 10211 and a second side 10212, the first side 10211 is opposite to the second side 10212, the first side 10211 is close to the substrate 101, and the second side 10212 is far away from the substrate 101. The second black matrix unit 1022 comprises a third side 10221 and a fourth side 10222, the third side 10221 is opposite to the fourth side 10222, the third side 10221 is close to the substrate 101, and the fourth side 10222 is far away from the substrate 101. The second side 10212 is attached to the third side 10221.

It may be understood that the second side 10212 is completely attached to the third side 10221. That is, a length of the second side 10212 is equal to a length of the third side 10221. Furthermore, the color resist unit 103 is formed by printing between the adjacent black matrix blocks 102, and the second black matrix unit 1022 is composed of a hydrophobic material, so when the ink between adjacent black matrix blocks 102 is cured to form the color resist unit 103, and the ink may not hang on a side wall of the second black matrix unit 1022. Therefore, a thickness of the formed color resist unit 103 is equal to a thickness of the first black matrix unit 1021, and the color resist unit 103 has a convex arc shape on a side away from the substrate 101. Therefore, the thickness of the color resist unit 103 may be precisely controlled by controlling the thickness of the first black matrix unit 1021.

Referring to FIG. 3, it is a second schematic structural view of a black matrix block and a color resist unit according to one embodiment of the present invention. The black matrix block 102 comprises a first black matrix unit 1023 and a second black matrix unit 1024. The first black matrix unit 1023 comprises a first side 10231 and a second side 10232, the first side 10231 is opposite to the second side 10232, the first side 10231 is close to the substrate 101, and the second side 10232 is far away from the substrate 101. The second black matrix unit 1024 comprises a third side 10241 and a fourth side 10242, the third side 10241 is opposite to the fourth side 10242, the third side 10241 is close to the substrate 101, and the fourth side 10242 is far away from the substrate 101. The second side 10232 is attached to the third side 10241.

It may be understood that the second side 10232 is incompletely attached to the third side. That is, a length of the second side 10232 is not equal to a length of the third side 10241.

At this time, the length of the second side 10232 is greater than the length of the third side 10241. Therefore, the color resist unit 103 is formed between adjacent black matrix blocks 102, and the first black matrix unit 1023 is composed of hydrophilic material, so the ink is aggregated at a position where the second side 10232 is not attached to the third side 10241, and the formed color resist unit 103 comprises a first part 1031 and a second part 1032 disposed on the first part 1031. A thickness of the first part 1031 is equal to a thickness of the first black matrix unit 1023, and the first part 1031 comprises a trapezoid shape. Because the second black matrix unit 1024 is composed of a hydrophobic material, the ink may not hang on a side wall of the second black matrix unit 1024. Therefore, the second part 1032 has an arc shape, and a thickness of the second part 1032 is less than a thickness of the second black matrix unit 1024.

The difference between the color resist unit 103 formed in FIG. 3 and the color resist unit 103 formed in FIG. 2 is that the thickness of the color resist unit 103 formed in FIG. 3 is thicker than the thickness of the color resist unit 103 formed in FIG. 2. Moreover, an arc shape of a side of the color resist unit 103 away from the substrate in FIG. 3 is much more convex than an arc shape of a side the color resist unit 103 away from the substrate in FIG. 2 on the side away from the substrate, and the arc of the side of the color resist unit 103 away from the substrate in FIG. 3 is also larger. Therefore, by controlling the length of the second side 10232 and the length of the third side 10241, the technical effect of adjusting the appearance of the color resist unit 103 may be achieved.

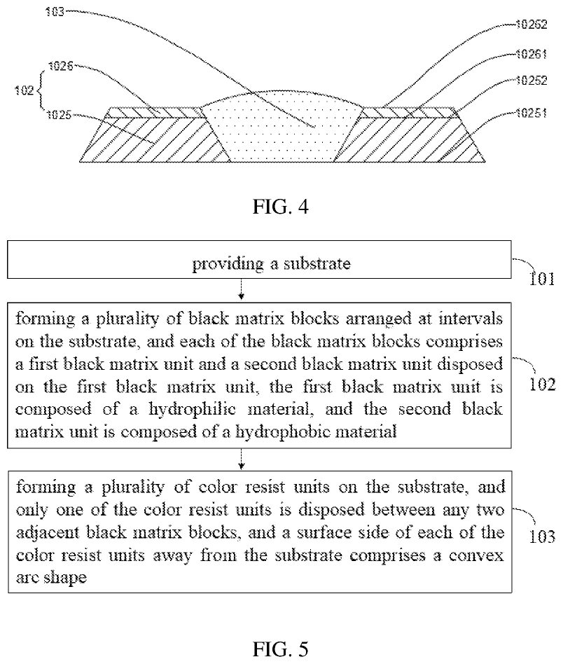

Referring to FIG. 4, it is a third schematic structural view of a black matrix block and a color resist unit according to one embodiment of the present invention. The black matrix block 102 comprises a first black matrix unit 1025 and a second black matrix unit 1026. The first black matrix unit 1025 comprises a first side 10251 and a second side 10252, the first side 10251 is opposite to the second side 10252, the first side 10251 is close to the substrate 101, and the second side 10252 is far away from the substrate 101. The second black matrix unit 1026 comprises a third side 10261 and a fourth side 10262, the third side 10261 is opposite to the fourth side 10262, the third side 10261 is close to the substrate 101, and the fourth side 10262 is far away from the substrate 101. The second side 10252 is attached to the third side 10261.

It may be understood that the second side 10252 is completely attached to the third side 10261. That is, a length of the second side 10252 is equal to a length of the third side 10261, and a thickness of the first black matrix unit 1025 is greater than a thickness of the second black matrix unit 1026. Therefore, when the color resist unit 103 is formed between adjacent black matrix blocks 102, the ink covers the second black matrix unit 1026 due to less thickness of the second black matrix unit 1026. The second black matrix unit 1022 is composed of a hydrophobic material, and the ink may not hang on a side wall of the second black matrix unit 1022. Therefore, the thickness of the color resist unit 103 is equal to a total thickness of the first black matrix unit 1021 and the second black matrix unit 1026.

In the present invention, a color filter is provided. A black matrix with a double-layer structure is provided, and the double-layer structure of the black matrix is composed of different materials. An upper layer structure of the black matrix is composed of a hydrophobic material. A lower layer structure of the black matrix is composed of a hydrophilic material. Therefore, a thickness of the color filter may be precisely controlled by controlling a size of the upper layer structure of the black matrix and a size of the lower layer structure of the black matrix. Accordingly, technical problem that the thickness of the color resist unit in the color filter of the prior art cannot be effectively controlled is solved.

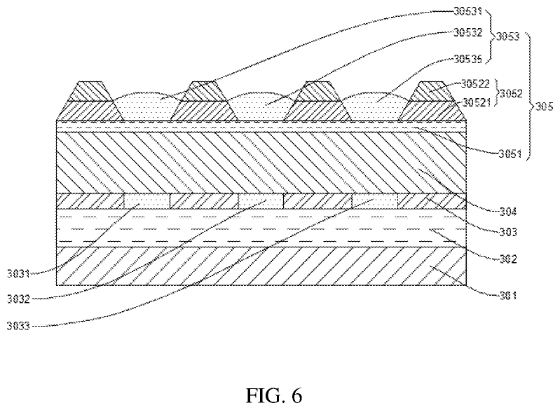

Referring to FIG. 5, it is a schematic flowchart of a method of manufacturing a color filter according to one embodiment of the present invention. A method of manufacturing a color filter comprises steps as follows: step 101, provide a substrate; step 102, forming a plurality of black matrix blocks arranged at intervals on the substrate, and each of the black matrix blocks comprises a first black matrix unit and a second black matrix unit disposed on the first black matrix unit, the first black matrix unit is composed of a hydrophilic material, and the second black matrix unit is composed of a hydrophobic material; and step 103, forming a plurality of color resist units on the substrate, and only one of the color resist units is disposed between any two adjacent black matrix blocks, and a surface side of each of the color resist units away from the substrate comprises a convex arc shape.

It may be understood that the color resist unit is formed by inkjet printing in a spacing between adjacent black matrixes, and the second black matrix unit is composed of a hydrophobic material, so when the color ink is cured, the ink may not hang on a side wall of the second black matrix unit, and the color ink may be uniformly cured on a side close to the substrate. Therefore, the side of the color resist unit away from the substrate has a convex arc shape.

In the present invention, a color filter and a method of manufacturing thereof are provided. A black matrix with a double-layer structure is provided, and the double-layer structure of the black matrix is composed of different materials. An upper layer structure of the black matrix is composed of a hydrophobic material. A lower layer structure of the black matrix is composed of a hydrophilic material. Therefore, a thickness of the color filter may be precisely controlled by controlling a size of the upper layer structure of the black matrix and a size of the lower layer structure of the black matrix. Accordingly, technical problem that the thickness of the color resist unit in the color filter of the prior art cannot be effectively controlled is solved.

In the present invention, a method of manufacturing thereof is provided. A black matrix with a double-layer structure is provided, and the double-layer structure of the black matrix is composed of different materials. An upper layer structure of the black matrix is composed of a hydrophobic material. A lower layer structure of the black matrix is composed of a hydrophilic material. Therefore, a thickness of the color filter may be precisely controlled by controlling a size of the upper layer structure of the black matrix and a size of the lower layer structure of the black matrix. Accordingly, technical problem that the thickness of the color resist unit in the color filter of the prior art cannot be effectively controlled is solved.

Referring to FIG. 6, it is a schematic structural view of a display panel according to one embodiment of the present invention. The display panel comprises a substrate 301, a thin film transistor layer 302, an electroluminescent layer 303, a thin film packaging layer 304, and a color filter 305. The thin film transistor layer 302 is disposed on the substrate 301. The electroluminescence layer 303 is disposed on the thin film transistor layer 302. The thin film packaging layer 304 is disposed on the electroluminescence layer 303. The color filter 305 is disposed on the thin film packaging layer 304. The color filter 305 comprises the color filter described in the above embodiments.

It may be understood that the electroluminescent layer 303 is provided with a red pixel unit 3031, a green pixel unit 3032, and a blue pixel unit 3033. The color filter 305 comprises a substrate 3051, a black matrix 3052, and a color resist unit 3053. The black matrix 3052 comprises a first black matrix unit 30521 and a second black matrix unit 30522. The color resist unit 3053 comprises a red color resist unit 30531, a green color resist unit 30532, and a blue color resist unit 30533. The red pixel unit 3031 of the electroluminescent layer 303 corresponds to the red color resist unit 30531 in the color filter 305 one-to-one. The green pixel unit 3032 of the electroluminescence layer 303 corresponds to the green color resist unit 30532 in the color filter 305 one-to-one. The blue pixel unit 3033 of the electroluminescence layer 303 corresponds to the blue color resist unit 30533 in the color filter 305 one-to-one.

In the display panel of the present invention. A black matrix with a double-layer structure is provided, and the double-layer structure of the black matrix is composed of different materials. An upper layer structure of the black matrix is composed of a hydrophobic material. A lower layer structure of the black matrix is composed of a hydrophilic material. Therefore, a thickness of the color filter may be precisely controlled by controlling a size of the upper layer structure of the black matrix and a size of the lower layer structure of the black matrix. Accordingly, technical problem that the thickness of the color resist unit in the color filter of the prior art cannot be effectively controlled is solved.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A color filter, comprising:
a substrate;
a plurality of black matrix blocks, wherein the plurality of black matrix blocks are disposed on the substrate at intervals, and each of the black matrix blocks comprises a first black matrix unit and a second black matrix unit disposed on the first black matrix unit; wherein in any two adjacent black matrix blocks, a spacing between two adjacent first black matrix units is less than a spacing between two adjacent second black matrix units; wherein the first black matrix unit is composed of a hydrophilic material, and the hydrophilic material comprises at least one of metal oxides and metal sulfides; and wherein the second black matrix unit is composed of a hydrophobic material, and the second black matrix unit comprises at least one of fluorine-containing organic resin and fluorine-free acrylate; and
a plurality of color resist units, wherein the plurality of color resist units are disposed on the substrate, only one of the color resist units is disposed between any two adjacent black matrix blocks, and a surface side of each of the color resist units away from the substrate comprises a convex arc shape.

2. The color filter according to claim 1, wherein the first black matrix unit and the second black matrix unit comprise a trapezoid shape.

3. The color filter according to claim 2, wherein the first black matrix unit comprises a first side and a second side, the first side is opposite to the second side, the first side is close to the substrate, and the second side is far away from the substrate;
wherein the second black matrix unit comprises a third side and a fourth side, the third side is opposite to the fourth side, the third side is close to the substrate, and the fourth side is far away from the substrate; and
wherein the second side is attached to the third side.

4. The color filter according to claim 3, wherein the second side is completely attached to the third side.

5. The color filter according to claim 4, wherein a length of the second side is equal to a length of the third side, and a thickness of the color resist unit is equal to a thickness of the first black matrix unit.

6. The color filter according to claim 4, wherein when a length of the second side is equal to a length of the third side and a thickness of the first black matrix unit is greater than a thickness of the second black matrix unit, a thickness of the color resist unit is equal to a total thickness of the first black matrix unit and the second black matrix unit.

7. The color filter according to claim 3, wherein the second side is incompletely attached to the third side.

8. The color filter according to claim 7, wherein a length of the second side is greater than a length of the third side;
wherein the color resist unit comprises a first part and a second part disposed on the first part;
wherein a thickness of the first part is equal to a thickness of the first black matrix unit, and the first part comprises a trapezoid shape; and
wherein a thickness of the second part is less than a thickness of the second black matrix unit, and the second part comprises an arc shape.

9. A color filter, comprising:
a substrate;
a plurality of black matrix blocks, wherein the plurality of black matrix blocks are disposed on the substrate at intervals, and each of the black matrix blocks comprises a first black matrix unit and a second black matrix unit disposed on the first black matrix unit; and wherein the first black matrix unit is composed of a hydrophilic material, and the second black matrix unit is composed of a hydrophobic material; and
a plurality of color resist units, wherein the plurality of color resist units are disposed on the substrate, only one of the color resist units is disposed between any two adjacent black matrix blocks, and a surface side of each of the color resist units away from the substrate comprises a convex arc shape.

10. The color filter according to claim 9, wherein the first black matrix unit comprises at least one of metal oxides and metal sulfides.

11. The color filter according to claim 9, wherein the second black matrix unit comprises at least one of fluorine-containing organic resin and fluorine-free acrylate.

12. The color filter according to claim 9, wherein in any two adjacent black matrix blocks, a spacing between two adjacent first black matrix units is less than a spacing between two adjacent second black matrix units.

13. The color filter according to claim 12, wherein the first black matrix unit and the second black matrix unit comprise a trapezoid shape.

14. The color filter according to claim 13, wherein the first black matrix unit comprises a first side and a second side, the first side is opposite to the second side, the first side is close to the substrate, and the second side is far away from the substrate;
wherein the second black matrix unit comprises a third side and a fourth side, the third side is opposite to the fourth side, the third side is close to the substrate, and the fourth side is far away from the substrate; and
wherein the second side is attached to the third side.

15. The color filter according to claim 14, wherein the second side is completely attached to the third side.

16. The color filter according to claim 15, wherein a length of the second side is equal to a length of the third side, and a thickness of the color resist unit is equal to a thickness of the first black matrix unit.

17. The color filter according to claim 15, wherein when a length of the second side is equal to a length of the third side and a thickness of the first black matrix unit is greater than a thickness of the second black matrix unit, a thickness of the color resist unit is equal to a total thickness of the first black matrix unit and the second black matrix unit.

18. The color filter according to claim 14, wherein the second side is incompletely attached to the third side.

19. The color filter according to claim 18, wherein a length of the second side is greater than a length of the third side;
wherein the color resist unit comprises a first part and a second part disposed on the first part;
wherein a thickness of the first part is equal to a thickness of the first black matrix unit, and the first part comprises a trapezoid shape; and
wherein a thickness of the second part is less than a thickness of the second black matrix unit, and the second part comprises an arc shape.

20. A method of manufacturing a color filter, comprising:
providing a substrate;
forming a plurality of black matrix blocks arranged at intervals on the substrate, wherein each of the black matrix blocks comprises a first black matrix unit and a second black matrix unit disposed on the first black matrix unit, the first black matrix unit is composed of a hydrophilic material, and the second black matrix unit is composed of a hydrophobic material; and
forming a plurality of color resist units on the substrate, wherein only one of the color resist units is disposed between any two adjacent black matrix blocks, and a surface side of each of the color resist units away from the substrate comprises a convex arc shape.
